(19) United States
(12) Patent Application Publication
(10) Pub. No.: US 2025/0347301 A1
(43) Pub. Date: Nov. 13, 2025

(54) LATCH DEVICE INSERTION AND RELEASE MECHANISM

(71) Applicant: DELL PRODUCTS L.P., Round Rock, TX (US)

(72) Inventors: Chen Zhao, Shanghai (CN); John Donachy, Austin, TX (US); Amrita Sidhu Maguire, Cedar Park, TX (US); Qingqiang Guo, Shanghai (CN); Harris Di Dihuweii, Shanghai (CN)

(21) Appl. No.: 18/662,135

(22) Filed: May 13, 2024

(51) Int. Cl. F16B 2/02; H05K 5/02; H05K 7/14

(52) U.S. Cl. CPC F16B 2/02; H05K 5/023; H05K 7/1489

(57) ABSTRACT

A latching mechanism includes a release button integrated with a handle. The release button is coupled to a latch that is configured to rotate and disengage from a sidewall. A sliding rail is coupled to the handle and movably coupled to the sidewall via an ejector and a ramp. The ramp moves subsequent to the latch being disengaged from the sidewall, and the ejector rotates and traverses from a first end of the ramp to a second end of the ramp.

### FIELD OF THE DISCLOSURE

The present disclosure generally relates to information handling systems, and more particularly relates to a latch device insertion and release mechanism.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A latching mechanism includes a release button integrated with a handle. The release button is coupled to a latch that is configured to rotate and disengage from a sidewall. A sliding rail is coupled to the handle and movably coupled to the sidewall via an ejector and a ramp. The ramp moves subsequent to the latch being disengaged from the sidewall, and the ejector rotates and traverses from a first end of the ramp to a second end of the ramp.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram illustrating an information handling system, according to an embodiment of the present disclosure;

FIG. 2 shows a perspective rear view of a chassis, according to an embodiment of the present disclosure;

FIGS. 3-6B are perspective views of a chassis housing an information handling system, according to an embodiment of the present disclosure;

FIGS. 7-8 are side views of a latch assembly, according to an embodiment of the present disclosure;

FIGS. 9-10 are perspective views of an information handling system, according to an embodiment of the present disclosure;

FIGS. 11-13 are perspective views of a chassis housing an information handling system, according to an embodiment of the present disclosure; and

FIGS. 14-16 are side views of a latch assembly with a cross-sectional view of a handle, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

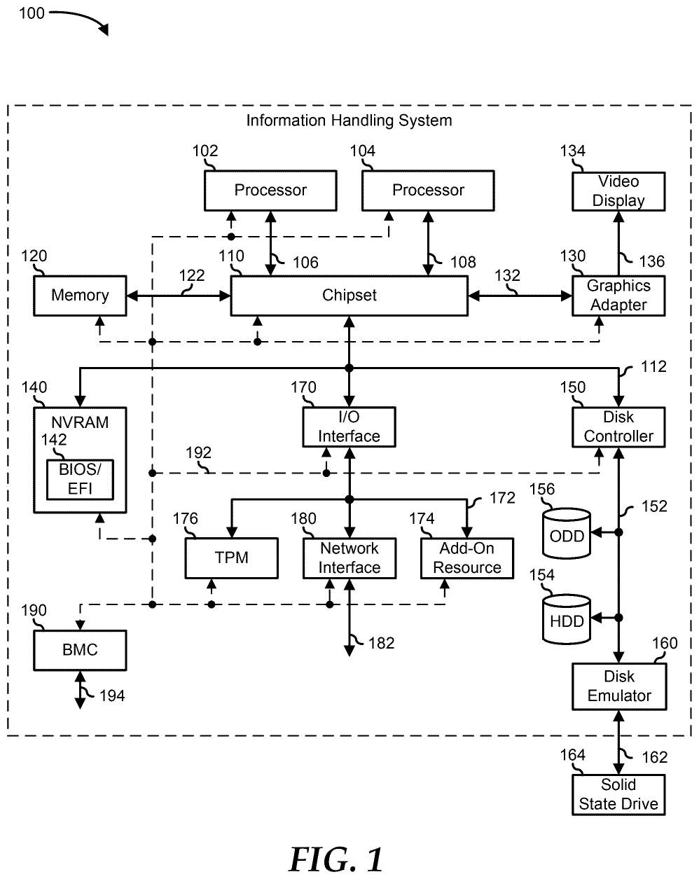

FIG. 1 illustrates an embodiment of an information handling system 100 including processors 102 and 104, a chipset 110, a memory 120, a graphics adapter 130 connected to a video display 134, a non-volatile RAM (NVRAM) 140 that includes a basic input and output system/extensible firmware interface (BIOS/EFI) module 142, a disk controller 150, a hard disk drive (HDD) 154, an optical disk drive 156, a disk emulator 160 connected to a solid-state drive (SSD) 164, an input/output (I/O) interface 170 connected to an add-on resource 174 and a trusted platform module (TPM) 176, a network interface 180, and a baseboard management controller (BMC) 190. Processor 102 is connected to chipset 110 via processor interface 106, and processor 104 is connected to the chipset via processor interface 108. In a particular embodiment, processors 102 and 104 are connected together via a high-capacity coherent fabric, such as a HyperTransport link, a QuickPath Interconnect, or the like. Chipset 110 represents an integrated circuit or group of integrated circuits that manage the data flow between processors 102 and 104 and the other elements of information handling system 100. In a particular embodiment, chipset 110 represents a pair of integrated circuits, such as a northbridge component and a southbridge component. In another embodiment, some or all of the functions and features of chipset 110 are integrated with one or more of processors 102 and 104.

Memory 120 is connected to chipset 110 via a memory interface 122. An example of memory interface 122 includes a Double Data Rate (DDR) memory channel and memory 120 represents one or more DDR Dual In-Line Memory Modules (DIMMs). In a particular embodiment, memory interface 122 represents two or more DDR channels. In another embodiment, one or more of processors 102 and 104 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 120 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 130 is connected to chipset 110 via a graphics interface 132 and provides a video display output 136 to a video display 134. An example of a graphics interface 132 includes a Peripheral Component Interconnect-Express (PCIe) interface and graphics adapter 130 can include a four-lane (x4) PCIe adapter, an eight-lane (x8) PCIe adapter, a 16-lane (x16) PCIe adapter, or another configuration, as needed or desired. In a particular embodiment, graphics adapter 130 is provided down on a system printed circuit board (PCB). Video display output 136 can include a Digital Video Interface (DVI), a High-Definition Multimedia Interface (HDMI), a DisplayPort interface, or the like, and video display 134 can include a monitor, a smart television, an embedded display such as a laptop computer display, or the like.

NVRAM 140, disk controller 150, and I/O interface 170 are connected to chipset 110 via an I/O channel 112. An example of I/O channel 112 includes one or more point-to-point PCIe links between chipset 110 and each of NVRAM 140, disk controller 150, and I/O interface 170. Chipset 110 can also include one or more other I/O interfaces, including a PCIe interface, an Industry Standard Architecture (ISA) interface, a Small Computer Serial Interface (SCSI) interface, an Inter-Integrated Circuit (I2C) interface, a System Packet Interface, a Universal Serial Bus (USB), another interface, or a combination thereof. NVRAM 140 includes BIOS/EFI module 142 that stores machine-executable code (BIOS/EFI code) that operates to detect the resources of information handling system 100, to provide drivers for the resources, to initialize the resources, and to provide common access mechanisms for the resources. The functions and features of BIOS/EFI module 142 will be further described below.

Disk controller 150 includes a disk interface 152 that connects the disc controller to a hard disk drive (HDD) 154, to an optical disk drive (ODD) 156, and to disk emulator 160. An example of disk interface 152 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 160 permits SSD 164 to be connected to information handling system 100 via an external interface 162. An example of external interface 162 includes a USB interface, an institute of electrical and electronics engineers (IEEE) 1394 (Firewire) interface, a proprietary interface, or a combination thereof. Alternatively, SSD 164 can be disposed within information handling system 100.

I/O interface 170 includes a peripheral interface 172 that connects the I/O interface to add-on resource 174, to TPM 176, and to network interface 180. Peripheral interface 172 can be the same type of interface as I/O channel 112 or can be a different type of interface. As such, I/O interface 170 extends the capacity of I/O channel 112 when peripheral interface 172 and the I/O channel are of the same type, and the I/O interface translates information from a format suitable to the I/O channel to a format suitable to the peripheral interface 172 when they are of a different type. Add-on resource 174 can include a data storage system, an additional graphics interface, a network interface card (NIC), a sound/video processing card, another add-on resource, or a combination thereof. Add-on resource 174 can be on a main circuit board, on separate circuit board, or add-in card disposed within information handling system 100, a device that is external to the information handling system, or a combination thereof.

Network interface 180 represents a network communication device disposed within information handling system 100, on a main circuit board of the information handling system, integrated onto another component such as chipset 110, in another suitable location, or a combination thereof. Network interface 180 includes a network channel 182 that provides an interface to devices that are external to information handling system 100. In a particular embodiment, network channel 182 is of a different type than peripheral interface 172 and network interface 180 translates information from a format suitable to the peripheral channel to a format suitable to external devices.

In a particular embodiment, network interface 180 includes a NIC or host bus adapter (HBA), and an example of network channel 182 includes an InfiniBand channel, a Fibre Channel, a Gigabit Ethernet channel, a proprietary channel architecture, or a combination thereof. In another embodiment, network interface 180 includes a wireless communication interface, and network channel 182 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 182 can be connected to an external network resource (not illustrated). The network resource can include another information handling system, a data storage system, another network, a grid management system, another suitable resource, or a combination thereof.

BMC 190 is connected to multiple elements of information handling system 100 via one or more management interface 192 to provide out-of-band monitoring, maintenance, and control of the elements of the information handling system. As such, BMC 190 represents a processing device different from processor 102 and processor 104, which provides various management functions for information handling system 100. For example, BMC 190 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 190 can vary considerably based on the type of information handling system. BMC 190 can operate in accordance with an Intelligent Platform Management Interface (IPMI). Examples of BMC 190 include an Integrated Dell® Remote Access Controller (iDRAC).

Management interface 192 represents one or more out-of-band communication interfaces between BMC 190 and the elements of information handling system 100, and can include an Inter-Integrated Circuit (I2C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 100, that is apart from the execution of code by processors 102 and 104 and procedures that are implemented on the information handling system in response to the executed code.

BMC 190 operates to monitor and maintain system firmware, such as code stored in BIOS/EFI module 142, option ROMs for graphics adapter 130, disk controller 150, add-on resource 174, network interface 180, or other elements of information handling system 100, as needed or desired. In particular, BMC 190 includes a network interface 194 that can be connected to a remote management system to receive firmware updates, as needed or desired. Here, BMC 190 receives the firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 190 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 190, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell Remote Access Controller Administrator (RACADM) utility, a Dell OpenManage Enterprise, a Dell OpenManage Server Administrator (OMSA) utility, a Dell OpenManage Storage Services (OMSS) utility, or a Dell OpenManage Deployment Toolkit (DTK) suite), a BIOS setup utility such as invoked by a “F2” boot option, or another protocol or API, as needed or desired.

In a particular embodiment, BMC 190 is included on a main circuit board (such as a baseboard, a motherboard, or any combination thereof) of information handling system 100 or is integrated onto another element of the information handling system such as chipset 110, or another suitable element, as needed or desired. As such, BMC 190 can be part of an integrated circuit or a chipset within information handling system 100. An example of BMC 190 includes an iDRAC, or the like. BMC 190 may operate on a separate power plane from other resources in information handling system 100. Thus BMC 190 can communicate with the management system via network interface 194 while the resources of information handling system 100 are powered off. Information can be sent from the management system to BMC 190 and the information can be stored in a RAM or NVRAM associated with the BMC. Information stored in the RAM may be lost after power-down of the power plane for BMC 190, while information stored in the NVRAM may be saved through a power-down/power-up cycle of the power plane for the BMC.

Information handling system 100 can include additional components and additional busses, not shown for clarity. For example, information handling system 100 can include multiple processor cores, audio devices, and the like. While a particular arrangement of bus technologies and interconnections is illustrated for the purpose of example, one of skill will appreciate that the techniques disclosed herein are applicable to other system architectures. Information handling system 100 can include multiple central processing units (CPUs) and redundant bus controllers. One or more components can be integrated together. Information handling system 100 can include additional buses and bus protocols, for example, I2C and the like. Additional components of information handling system 100 can include one or more storage devices that can store machine-executable code, one or more communications ports for communicating with external devices, and various input and output (I/O) devices, such as a keyboard, a mouse, and a video display.

For purposes of this disclosure information handling system 100 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 100 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 100 can include processing resources for executing machine-executable code, such as processor 102, a programmable logic array (PLA), an embedded device such as a System-on-a-Chip (SoC), or other control logic hardware. Information handling system 100 can also include one or more computer-readable media for storing machine-executable code, such as software or data.

Groups of information handling systems may be housed within data center environments. A data center may include a large number of information handling systems that are typically housed in a chassis and stacked within slots provided by racks. The racks may be organized into rows in a manner that allows an administrator to access information handling system components via the front and/or back of a rack. In some instances, the administrator may be able to service and replace components of a rack-mounted information handling system while the information handling system remains operational and installed within the rack. In other instances, the administrator may remove the information handling system from operation to service or replace an internal component.

The administrator may also be able to re-configure aspects of the operation of the information handling system through the coupling and de-coupling of cables to the various connectors that may be provided on the back of a chassis by a rear-facing chassis component. In these and other cases, the administrator should be able to access and service an information handling system as easily and safely as possible within the constraints of the information handling system being installed within a rack of a densely packed data center. Thus, the solution may have to accommodate a variety of hand sizes while considering different server rack configurations and constraints for the safe removal and insertion of an information handling system. Accordingly, the inventors have recognized a need for a tangible user interface solution provided by the present disclosure to balance optimal hand access within a constrained space that does not consume valuable real estate on a densely populated enterprise technology platform.

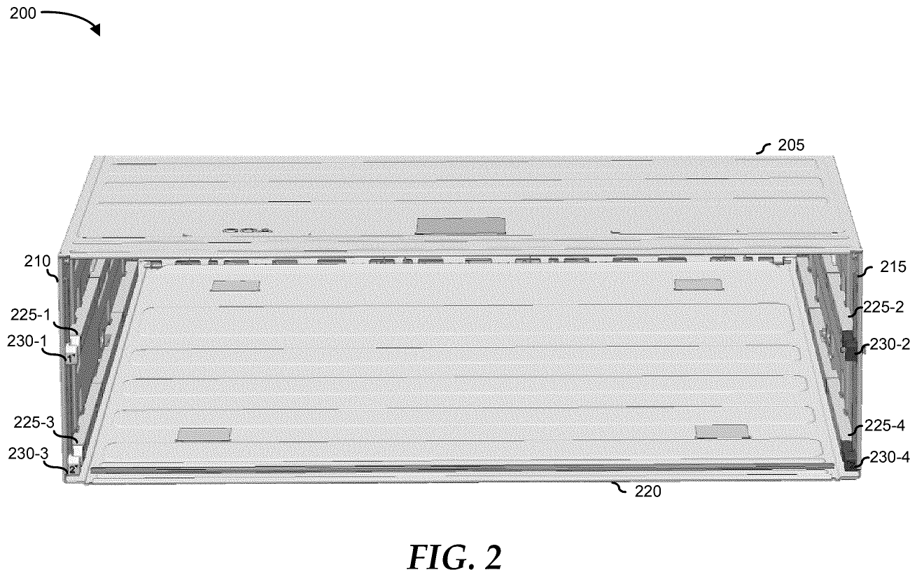

FIG. 2 shows a perspective rear view of a chassis 200 without an information handling system. Chassis 200 may be configured to house one or more information handling systems, wherein chassis 200 may be made of sheet metal or other material. Chassis 200 may be an exterior housing of a dual processor enclosure which includes a mid-plane between the front of storage devices, such as SSD, server nodes, etc. In one embodiment, chassis 200 may be a hollow rectangular block that includes a top cover 205, a sidewall 210, a sidewall 215, and a base 220. Sidewall 210 may be a left sidewall while sidewall 215 may be a right sidewall. Chassis 200 also includes rails 225-1 through 225-4 and retainers 230-1 through 230-4. Rails 225-1 and 225-2 may be positioned horizontally at opposite sides of chassis 200. Each one of rails 225-1 and 225-2 may be located at an inside section of sidewalls 210 and 215 respectively that is proximate to a midpoint between top cover 205 and base 220. Top cover 205 may be a top cover while base 220 may be a bottom section of chassis 200. For example, rail 225-1 may be located along a midpoint of an inside section of sidewall 210 while rail 225-2 may be located along a midpoint of an inside section of sidewall 215. Rails 225-1 and 225-2 may be movably coupled to an enclosure of an information handling system. As such, rails 225-1 and 225-2 may be used to slide the information handling system in and out of chassis 200, such that the information handling system may be housed in and/or extended out of chassis 200.

Rails 225-3 and 225-4 may be positioned horizontally at opposite sides of chassis 200. Rails 225-4 and 225-4 may be located proximate to base 220 at the inside section of sidewalls 210 and 215, respectively. For example, rail 225-3 may be located on the inside section of sidewall 210 while rail 225-4 may be located on the inside section of sidewall 215. Rails 225-3 and 225-4 may be movably coupled to sliding rails of another information handling system. As such, rails 225-3 and 225-4 may be used by the sliding rails of the other information handling system to slide the information handling system in and out of chassis 200, such that the other information handling system may be housed in and extended out of chassis 200. Accordingly, in this example, chassis 200 may accommodate one or two information handling systems, wherein one of the information handling systems may be on top of the other information handling system. However, a chassis may be configured to accommodate more than two information handling systems.

Each one of retainers 230-1 through 230-4 may be configured to provide leverage for an ejector associated with a latching mechanism of an information handling system. Each one of retainers 230-1 through 230-4 may be located at an edge of rails 225-1 through 225-4 respectively, such that an associated ejector may push against a retainer.

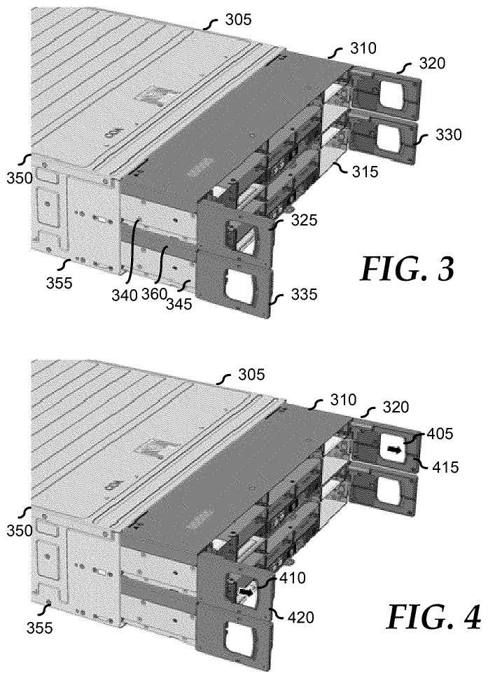

FIG. 3 shows a perspective view of a chassis 305 housing information handling systems 310 and 315. Chassis 305 is similar to chassis 200 of FIG. 2 while information handling systems 310 and 315 are similar to information handling system 100 of FIG. 1. Chassis 305 may include a top cover 350 and a sidewall 355. Top cover 350 may be similar to top cover 205 of FIG. 2. Sidewall 355 may be similar to sidewall 210 of FIG. 2. In this example, information handling systems 310 and 315 may be at a default position, wherein their enclosures are latched in chassis 305 via one or more latch mechanisms. However, the enclosures may be removed or extracted from chassis 305. Each of the enclosures may include a top, bottom, a left sidewall, and a right sidewall. For example, an enclosure of information handling system 315 includes a top cover 360 and a sidewall 345.

Similar to chassis 200 of FIG. 2, chassis 305 may include a pair of rails that receive information handling system 310. Chassis 305 may also include another pair of rails that receives the enclosure of information handling system 315. In a data center environment, chassis 305 along with other chassis may be stacked and housed in a rack. A data center may house multiple racks side by side. Each one of the racks may have a number of cables routed along its back, also referred to as a hot aisle. The cables can include data and/or power cables to be used by information handling systems 310 and 315, among others. Accordingly, each one of the information handling systems may include connectors that can be retractably coupled with the cables. With the increased pin density of the connectors, the force required to extract or insert the connectors has risen. For example, the force required to unseat an array of connector pins from a backplane of chassis 305 can surpass a 100-pound force.

Each one of the information handling systems may be kept securely in place in the chassis by a pair of latch device insertion and release mechanisms, also referred to herein simply as latch mechanisms. The latch mechanism may be a trigger-activated release and insertion solution that allows a user to extract or insert an information handling system in the chassis. To minimize real estate intrusion, each one of the pair of latch mechanisms is located at one end of the information handling system without utilizing front or rear panel real-estate for lever mechanisms. In this example, information handling system 310 includes latch mechanisms 320 and 325. Information handling system 315 includes latch mechanisms 330 and 335. Each one of the latch mechanisms may be embedded or coupled to a sidewall of an enclosure of information handling system 315. For example, latch mechanism 325 may be coupled to a sidewall 340 while latch mechanism 335 may be coupled to sidewall 345. Enclosures of information handling systems 310 and 315 may be slidable and extendable horizontally to a service position to allow a service technician to service information handling systems 310 and 315, respectively. The enclosures may be a single server node chassis that is configured to be inserted or extracted from chassis 305.

For example, assuming that information handling systems 310 and 315 are storage processor nodes with one or more storage processor modules, at some point the service technician may have to replace one of the storage processor modules. In this scenario, latch mechanisms 320 and 325 may include handles that are designed to provide clearance, such that the hands of the service technician can safely grab the handles without possibly scraping a knuckle into another piece of equipment or cable in the process. In this example, the handles of latch mechanisms 320 and 325 are designed in a D-latch handle configuration to provide a user with the ability to grip the handles to pull and extend information handling system 310 while minimizing the handle's real-estate intrusion.

FIG. 4 shows a perspective view of chassis 305 and information handling systems 310 and 315. From the default position, illustrated in FIG. 3, the current illustration shows the location of a release button that is integrated with each handle. The present illustration also shows the direction of force applied to the release button. In this example, latch mechanism 320 includes a release button 405 that is integrated with a handle 415. Latch mechanism 325 includes a release button 410 that is integrated with a handle 420. Release button 405 may be configured to release latch mechanism 320 from a locked or latched position when a user presses release button 405 in a direction of an arrow. Similarly, release button 410 may be configured to release latch mechanism 325 from the locked or latched position when the user presses release button 410 in a direction of an arrow.

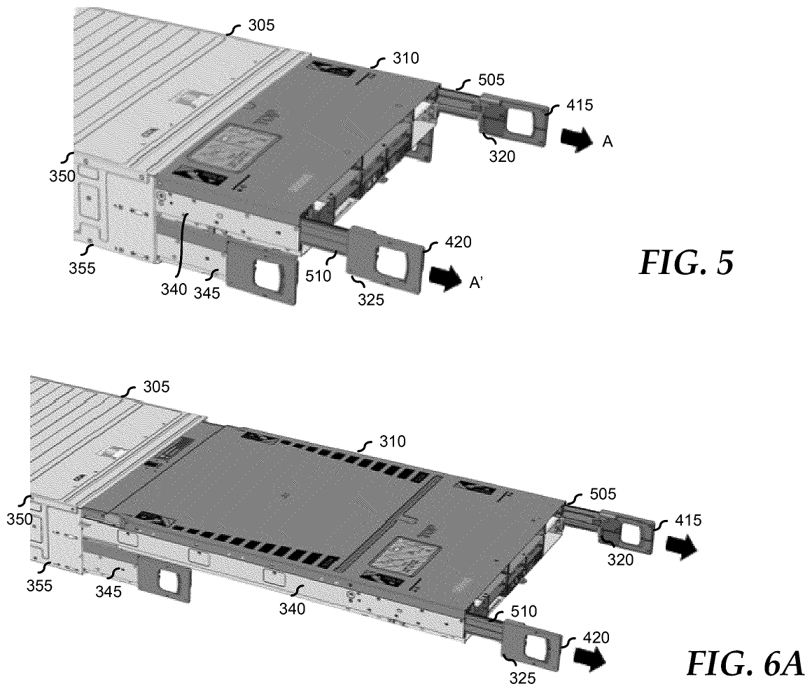

FIG. 5 shows a perspective view of chassis 305 with sliding rails of information handling system 310 ejected from chassis 305 using latch mechanisms 320 and 325. After the user presses release buttons 405 and 410, the user may use handles 415 and 420 to pull latch mechanisms 320 and 325 to extend sliding rails 505 and 510 from an enclosure of information handling system 310. As such, because sliding rails 505 and 510 may have been extended horizontally relative to chassis 305, the handles may be further out from the rack and/or chassis. This may allow enough space for the service technician to have a good grip. In this example, handles 415 and 420 of latch mechanisms 320 and 325 may be further out from chassis 305 which provides the user with space to grip handles 415 and 420 and pull information handling system 310 towards directions A and A′ respectively.

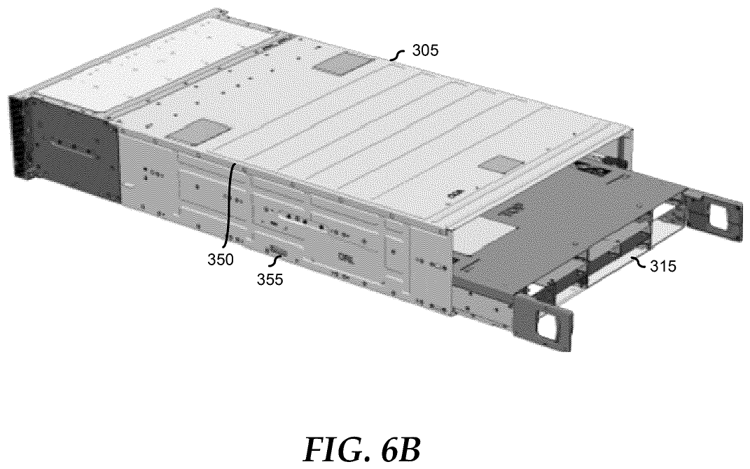

FIG. 6A shows a perspective view of chassis 305 with information handling system 310 ejected from chassis 305 using latch mechanisms 320 and 325. In this example, the service technician may have continued to use handles 415 and 420 to pull and extend information handling system 310 from chassis 305, such that information handling system 310 may be extended out of chassis 305. FIG. 6B shows a perspective view of chassis 305 with information handling system 310 fully extracted from chassis 305. Accordingly, chassis 305 includes information handling system 315.

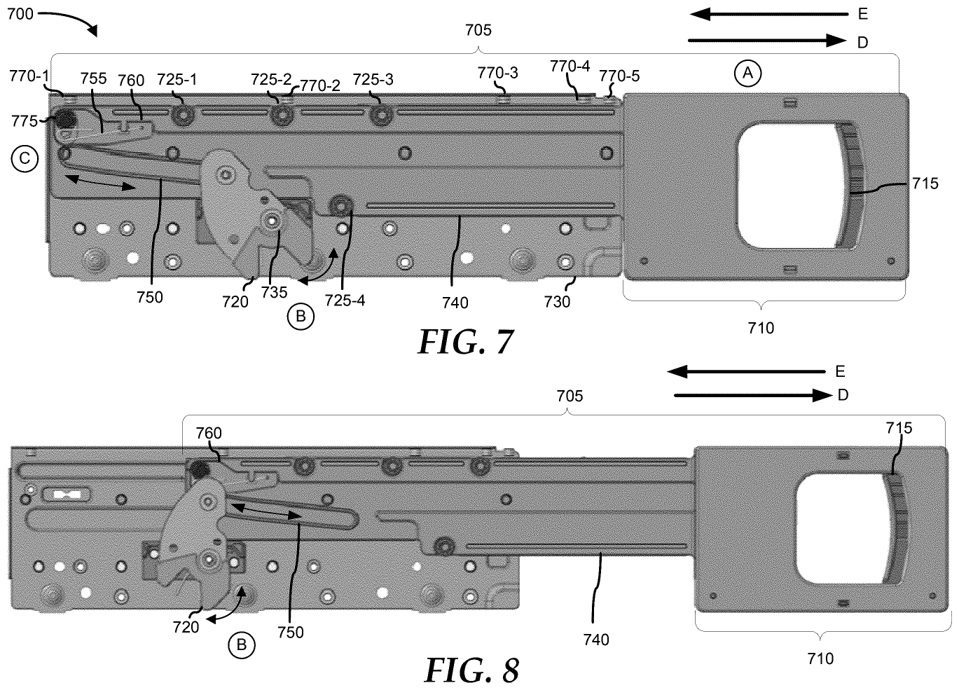

FIG. 7 shows a side view of a latch assembly 700 at a default position. Latch assembly 700 includes a latch mechanism 705 that is movably coupled or embedded to a sidewall 730. Sidewall 730 can be a portion of a sidewall that is similar to sidewall 340 of FIG. 3. Latch mechanism 705 includes a sliding rail 740 that is physically coupled to a handle 710 with an integrated release button 715. Handle 710 is similar to handle 415 of FIG. 4 while release button 715 is similar to release button 405 of FIG. 4. Latch mechanism 705 also includes a trigger 760, a ramp 750, and an ejector 720, wherein trigger 760, ramp 750, and ejector 720. Trigger 760 and ejector 720 may also be coupled to sidewall 730 by a coupling member. For example, trigger 760 may be movably coupled to sidewall 730 by a coupling member 775. In addition, trigger 760 may be secured to coupling member 775 via a pin 755. In one embodiment, trigger 760 may be configured to prevent sliding rail 740 from retracting too early by holding it in place until a trigger point is reached.

Ejector 720 which may be rotatably coupled to sidewall 730 by a coupling member 735. In one embodiment, coupling member 735 may be a spring that allows ejector 720 to rotate. In addition, ejector 720 may also be secured to coupling member 735 via a pin. Ramp 750 may be mechanically coupled to trigger 760 at one end. Ramp 750 may also be movably coupled to ejector 720 at another end. One or more springs, such as springs 770-1 through 770-5 may be used to guide sliding rail 740 in place as sliding rail 740 moves horizontally relative to sidewall 730 at direction D or E when pulled or pushed by the user, respectively. As such, sliding rail 740 may be housed in and then extended out of the enclosure. In addition, one or more rollers 725-1 through 725-4 may be used to minimize friction during the movement of sliding rail 740.

FIGS. 7-8 are annotated with a series of letters A-D. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations. At stage A, as a user pulls handle 710 towards a direction D, force applied by the user may result in ejector 720 to rotate upon reaching the trigger point at stage B. At stage C, ramp 750 may start to move towards the direction D. The sloped design of ramp 750 may provide an 8:1 mechanical force advantage at the start of ejecting the information handling system. The force may also be used in disengaging connectors of the information handling system from associated ports at a backplane of the chassis. Similarly, the sloped design of ramp 750 may also provide a mechanical force advantage when the user pushes latch mechanism 705 towards direction E. In particular, the mechanical force advantage may be used at the end of taking in the information handling system to engage the connectors of the information handling system to the associated ports at the backplane of the chassis.

FIG. 8 shows a side view of latch assembly 700 with latch mechanism 705 ejected from an enclosure. In this example, at stage D, the user may have continued pulling handle 710 subsequent to the user pulling it at FIG. 6A. As such, ejector 720 may continue rotating and traverse ramp 750 from one end that is distal to trigger 760 to another end that is proximate to trigger 760 until sliding rail 740 is fully ejected. Ramp 750 may include a rail that can be used by ejector 720 in traversing ramp 750 from one end to the other end. If the user continues pulling handle 710 towards the direction D, then ejector 720 with ramp 750 may apply a secondary force against a retainer of a rail of a chassis. For example, ejector 720 may push against the retainer to eject the connectors of an information handling system from the backplane of the chassis. This is performed prior to ejecting the information handling system from the chassis as depicted in FIG. 6A. Similarly, the user may push latch mechanism 705 towards direction E and re-insert sliding rail 740. Ejector 720 may rotate in the opposite direction and traverse ramp 750 from the end that is proximate to trigger 760 to the end that is distal from trigger 760 until sliding rail 740 is fully re-inserted. As the user continues to apply force and push the handle towards the direction E, the information handling system may be re-inserted in the chassis.

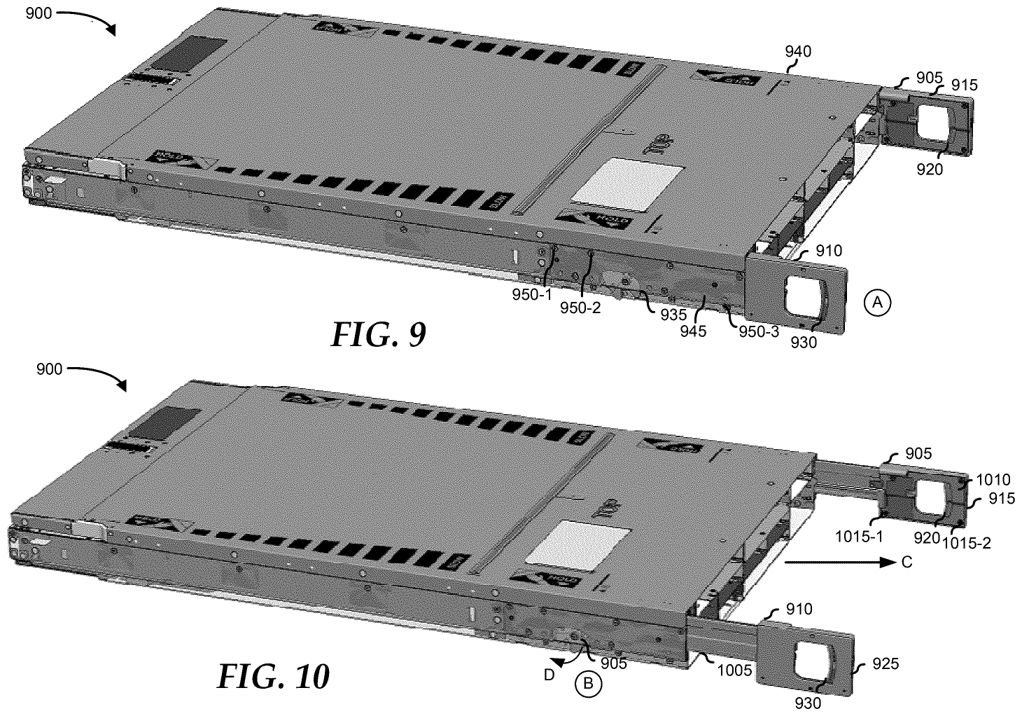

FIG. 9 shows a perspective view of an information handling system 900, wherein latch mechanisms 905 and 910 are at a default position. Information handling system 900 is similar to information handling system 310 of FIG. 3. Information handling system 900 includes an enclosure with a top cover 940 and a sidewall 945. Top cover 940 is similar to top cover 360 of FIG. 3. Sidewall 945 is similar to sidewall 345 of FIG. 3. Information handling system 900 includes latch mechanisms 905 and 910 which are similar to latch mechanisms 320 and 325 of FIG. 3. In one example, latch mechanism 910 may be coupled to sidewall 945 via one or more fasteners, such as fasteners 950-1, 950-2, and 950-3. Latch mechanism 905 includes an ejector and a handle 915 with an integrated release button 920. Latch mechanism 910 includes an ejector 935 and a handle 915 with an integrated release button 930. Handles 915 and 925 may be similar to handles 415 and 420 of FIG. 4. Accordingly, release buttons 920 and 930 may be similar to release buttons 405 and 410 of FIG. 4.

FIG. 10 shows a perspective view of information handling system 900, wherein latch mechanisms 905 and 910 are in an unlatched position. Handles of latch mechanisms may include a cover that is secured with one or more fasteners. For example, handle 915 includes a cover 1010 that is secured by fasteners, such as fasteners 1015-2 and 1015-2. FIGS. 9-10 are annotated with a series of letters A-B. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations. Referring to FIG. 9, at stage A, latch mechanisms 905 and 910 may be in a default or latched position. Accordingly, ejector 935, release button 920, and release button 930 which are associated with latch mechanism 910 may be in default positions. Referring to FIG. 10, at stage B, a user, like a service technician, may have pressed release buttons 920 and 930 while pulling handles 915 and 925 towards a direction C. As the user pulls handles 915 and 925, sliding rails that may be physically coupled to handles 915 and 925, such as a sliding rail 1005 may be ejected from information handling system 900 while ejector 905 may rotate towards a direction D.

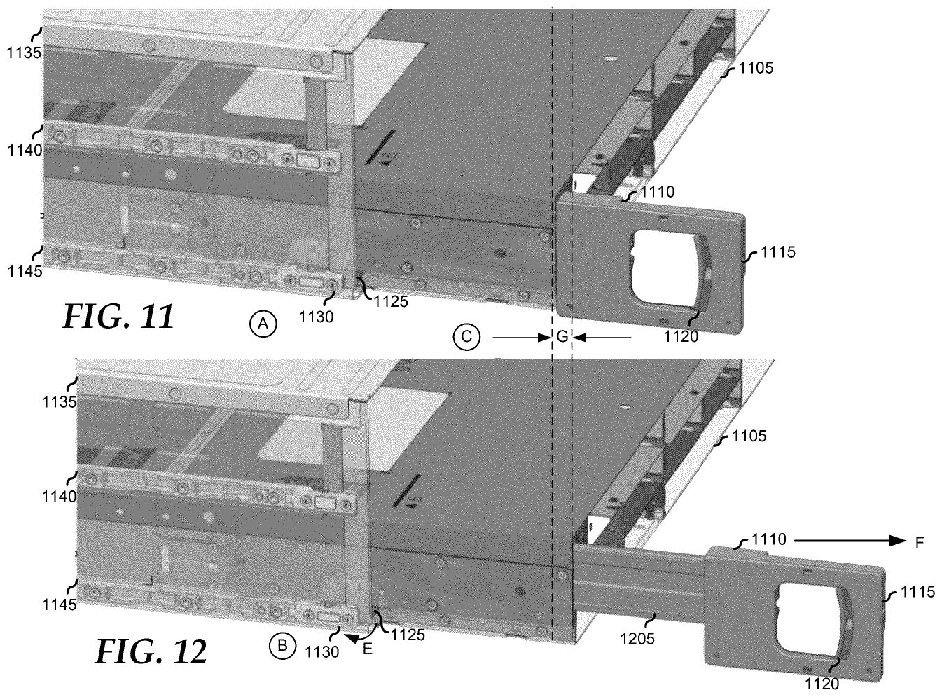

FIG. 11 shows a perspective view of an information handling system 1105 that is inserted in a chassis 1135. Chassis 1135 includes rails 1140 and 1145. Rail 1140 includes a retainer. Similarly, rail 1145 also includes a retainer 1130. Information handling system 1105, which is similar to information handling system 900 of FIG. 9, includes a latch mechanism 1110 which further includes a handle 1115, a release button 1120, and an ejector 1125. Latch mechanism 1110 is similar to latch mechanism 910 of FIG. 9. Handle 1115 is similar to handle 925 of FIG. 9 while release button 1120 is similar to release button 930 of FIG. 9. The perspective view is depicted with a transparent view of a left sidewall, which is similar to sidewall 210 of FIG. 2, to show a location of rails 1140 and 1145 in chassis 1135. The perspective view also shows how information handling system 1105 may be inserted in chassis 1135 using rail 1140 and another rail on an opposite sidewall, similar to sidewall 215 of FIG. 2, of chassis 1135.

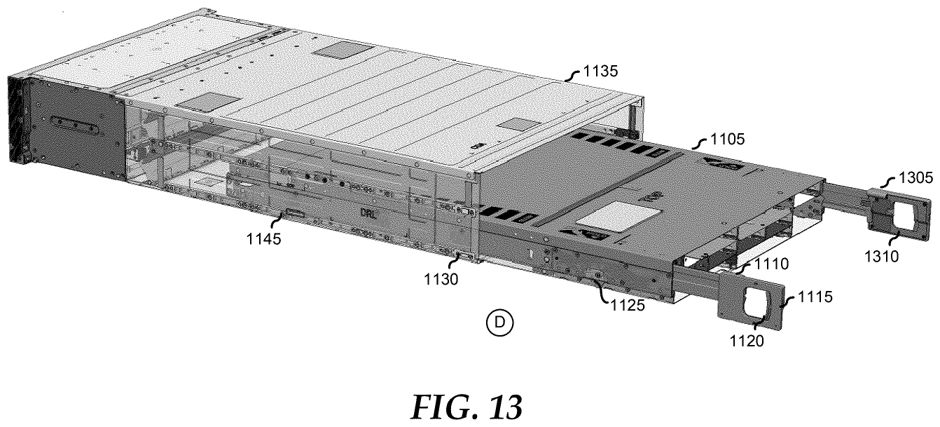

FIG. 12 shows a perspective view of information handling system 1105, wherein latch mechanism 1110 is in an unlatched position. Latch mechanism 1110 includes a sliding rail 1205 that is ejected out of information handling system 1105. FIG. 13 shows a perspective view of information handling system 1105, wherein latch mechanism 1110 is in an unlatched position and information handling system 1105 is ejected out of chassis 1135.

FIGS. 11-13 are annotated with a series of letters A-D. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations. Referring to FIG. 11, at stage A, latch mechanism 1110 may be in a default or latched position. Accordingly, ejector 1125 and release button 1120 may be in default positions. For example, ejector 1125 may be proximate to retainer 1130 but is not engaged with retainer 1130. Referring to FIG. 12, at stage B, a user, like a service technician may have pressed release button 1120 while pulling handle 1115 towards a direction F. As the user pulls handle 1115, a sliding rail 1205, which may be physically coupled to handle 1115, may be ejected from information handling system 1105 at stage C at a distance G. Distance G may be a short distance such as an inch or two, or a fraction thereof. At the same time, ejector 1125 may rotate towards a direction E and push against retainer 1130. Referring to FIG. 13, at stage D, the user may continue pulling latch mechanisms 1110 and 1305 using handles 1115 and 1310. As such, information handling system 1105 may be ejected from chassis 1135.

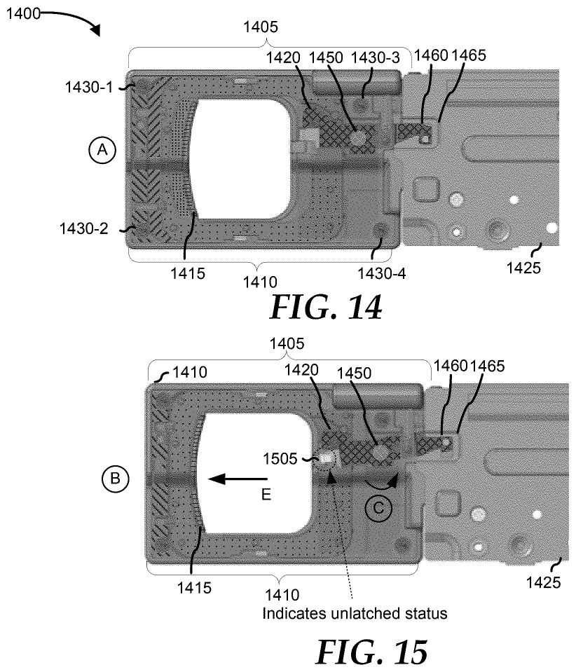

FIG. 14 shows a side view of a latch assembly 1400 at a default position with a cross-section view of a handle 1410. In particular, handle 1410 may show a view with its cover removed. For example, handle 1410, which is similar to handle 915 of FIG. 10, may be shown with cover 1010 removed. The default position may also be referred to as a latched position, wherein the latch mechanism is secured to a sidewall to prevent the latch mechanism from being ejected. This side view may be on an opposite side of the handle of a latch mechanism in reference to the handle shown in FIG. 7. In addition, this side view may be on the opposite side in reference to sidewall 730 shown in FIG. 7.

Latch assembly 1400 includes a latch mechanism 1405 that can be latched to a portion of sidewall 1425. Latch mechanism 1405 may be similar to latch mechanism 705 of FIG. 7 while sidewall 1425 may be similar to sidewall 730 of FIG. 7. Latch mechanism 1405 includes handle 1410 and a release button 1415. Handle 1410 is similar to handle 710 of FIG. 7 while release button 1415 is similar to release button 715 of FIG. 7. Release button 1415 may be configured to manipulate a camming release mechanism that enables an internal ramp mechanism to deliver or move a slide bar and unseat internal connectors from an internal backplane. Handle 1410 may also include one or more springs, such as springs 1430-1 through 1430-4 that may be configured to keep a latch 1420 of latch mechanism 1405 in the latched position. Latch 1420 may be rotatable coupled to handle 1410 via a rotating member 1450.

Latch 1420 may include a cam bar 1460 that extends at one end of latch 1420, wherein cam bar 1460 may be raised or lowered when latch 1420 rotates. As such, cam bar 1460 may be configured as a detent feature between latch 1420 and sidewall 1425 in order to retain latch 1420 in the default or latched position. Rotating member 1450 may be spring which may be configured to rotate latch 1420 when release button 1415 is pressed by a user. Cam bar 1460 may be configured to engage or disengage with a base 1465 when the release button 1415 is pressed, wherein base 1465 may be a notch at the end of sidewall 1425. Accordingly, cam bar 1460 may be configured to secure latch 1420 into base 1465 at the default position.

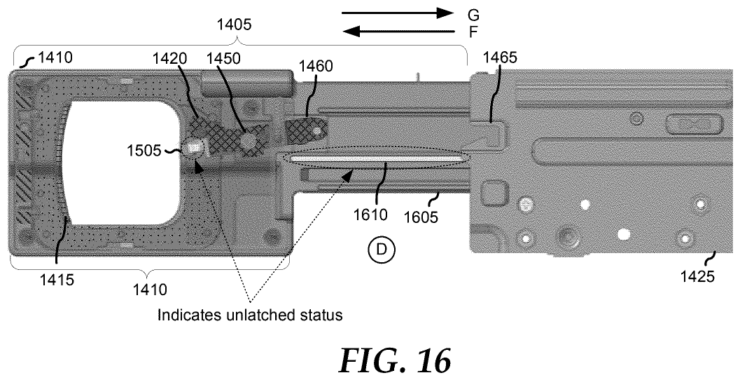

FIGS. 14-16 are annotated with a series of letters A-C. Each of these letters represents a stage of one or more operations. Although these stages are ordered for this example, the stages illustrate one example to aid in understanding this disclosure and should not be used to limit the claims. Subject matter falling within the scope of the claims can vary with respect to the order of the operations. Referring to FIG. 16, at stage A, latch 1420 may be configured to latch or engage latch mechanism 1405 into base 1465 of sidewall 1425 via cam bar 1460 at the default position.

FIG. 15 shows a side view of latch assembly 1400 at an unlatched position with a cross-section view of handle 1410. At stage B, a user may press release button 1415 towards a direction E to unlock latch 1420 from base 1465. As the user presses release button 1415, latch 1420 may rotate along rotating member 1450 and raise cam bar 1460. Raising cam bar 1460 may disengage cam bar 1460 from base 1465 which results in an unlatched or disengaged position. As latch 1420 is unlatched, a status indicator 1505 may be visible to indicate the unlatched or disengaged status. When latch 1420 is unlatched, a sliding rail associated with handle 1410 of latching mechanism 1405 may be able to eject or move. If status indicator 1505 is not visible, then latch mechanism 1405 may be in a latched or engaged position. Status indicator 1505 may have a color that is different from latch mechanism 1405 and sidewall 1425 to allow for greater visibility. In one example, status indicator 1505 may be yellow. Thus, latch 1420 may be configured to unlatch or disengage latch mechanism 1405 from base 1465 of sidewall 1425 via cam bar 1460 when the user presses release button 1415.

FIG. 16 shows a side view of latch assembly 1400 at an extended position with a cross-section view of handle 1410. At this point, latch mechanism 1405 assembly may be in a partial or fully extended position. As the user pulls latch mechanism 1405 using handle 1410, a sliding rail 1605 of latch mechanism 1405 may be ejected or extended from sidewall 1425 towards a direction F. At stage D, as sliding rail 1605, which is similar to sliding rail 740 of FIG. 7, may be ejected or extended horizontally, a status indicator 1610 associated with sliding rail 1605 may become visible. If status indicator 1610 is visible, then it may indicate that the latch mechanism 1405 is unlocked and sliding rail 1605 is ejected. Similarly, as the user pushes latch mechanism 1405 using handle 1410, sliding rail 1605 may be re-inserted along sidewall 1425 towards a direction G. As sliding rail 1605 is re-inserted, status indicator 1610 may no longer be visible. Accordingly, the user may press release button 1415 to engage latch 1420 of latch mechanism 1405 to base 1465 of sidewall 1425 via cam bar 1460. As latch 1420 is engaged with base 1465, status indicator 1505 may no longer be visible.

Although the embodiments provided herein describe a latch assembly of an information handling system that is a rack-mounted server, other embodiments may be implemented using other types of information handling systems. In the above-illustrated embodiments, the information handling system may be a storage node that would typically be installed within a chassis that in turn would be typically installed within slots of a rack. Installed in this manner, the information handling system may utilize certain resources provided by the chassis and/or rack, such as power and networking. In some embodiments, multiple information handling systems may be installed within a single chassis.

Those of ordinary skill in the art will appreciate that the configuration, hardware, and/or software components of a latch assembly may vary. For example, the illustrative components of the latch assembly are not intended to be exhaustive but rather are representative to highlight components that can be utilized to implement aspects of the present disclosure. For example, other devices and/or components may be used in addition to or in place of the devices/components depicted. The depicted example does not convey or imply any architectural or other limitations with respect to the presently described embodiments and/or the general disclosure. In the discussion of the figures, reference may also be made to components illustrated in other figures for the continuity of the description. In addition, some features of the latch assembly are not called out for clarity of illustration.

As used herein, a hyphenated form of a reference numeral refers to a specific instance of an element and the un-hyphenated form of the reference numeral refers to the collective or generic element. Thus, for example, spring “830-1” refers to an instance of a spring class, which may be referred to collectively as springs “830” and any one of which may be referred to generically as a spring “830.”

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A latching mechanism comprising:
a handle;
a release button integrated with the handle, wherein the release button is mechanically coupled to a latch that is configured to rotate and disengage from a sidewall; and
a sliding rail physically coupled to the handle, the sliding rail movably coupled to the sidewall via an ejector and a ramp, the ramp configured to move subsequent to the latch being disengaged from the sidewall, and the ejector configured to rotate and traverse from a first end of the ramp to a second end of the ramp.

2. The latching mechanism of claim 1, wherein the sliding rail is configured to move horizontally relative to the sidewall.

3. The latching mechanism of claim 1, wherein the ejector is rotably coupled to the sidewall.

4. The latching mechanism of claim 1, wherein the sidewall is associated with an enclosure of an information handling system.

5. The latching mechanism of claim 1, wherein the latch includes a cam bar that is configured to engage with a base on the sidewall.

6. The latching mechanism of claim 1, wherein the ramp may be configured to move relative to a force applied by a user using the handle.

7. The latching mechanism of claim 1, wherein the ramp may be configured to provide a mechanical advantage when disengaging a connector from a backplane.

8. The latching mechanism of claim 1, wherein the ramp may be configured to provide a mechanical advantage when engaging a connector to a backplane.

9. An information handling system, comprising:
an enclosure; and
a latching mechanism mechanically coupled to a sidewall of the enclosure, wherein the latching mechanism includes a release button that is configured to disengage a latch from the sidewall when the release button is pressed, and wherein a sliding rail of the latching mechanism is configured to eject when the latch is disengaged.

10. The information handling system claim 9, wherein the latch is configured to rotate and raise a cam bar from a base associated with the sidewall.

11. The information handling system of claim 9, wherein the sliding rail is mechanically coupled to an ejector.

12. The information handling system of claim 9, wherein the sliding rail is mechanically coupled to a sloped ramp.

13. The information handling system of claim 9, wherein the release button is spring loaded.

14. The information handling system of claim 9, wherein the sliding rail is configured to move horizontally when a handle of the latch mechanism is pulled by a user.

15. The information handling system of claim 9, wherein the sliding rail is configured to unseat a connector from an internal backplane.

16. A latch assembly comprising:
a sidewall; and
a latch mechanism movably coupled to the sidewall, the latch mechanism including:
a handle having a release button, wherein the release button is mechanically coupled to a latch that is configured to rotate and disengage from the sidewall; and
a sliding rail coupled to the handle, wherein the sliding rail is movably coupled to the sidewall via an ejector and a ramp, wherein the ramp is configured to move subsequent to the latch being disengaged from the sidewall, and the ejector is configured to rotate and traverse from a first end of the ramp to a second end of the ramp.

17. The latch assembly of claim 16, wherein the sliding rail is configured to move horizontally relative to the sidewall.

18. The latch assembly of claim 16, wherein the ejector is rotably coupled to the sidewall.

19. The latch assembly of claim 16, wherein the ramp is configured to disengage a connector from a backplane.

20. The latch assembly of claim 16, wherein the ramp is configured to engage a connector to a backplane.
